(19) United States
(12) Patent Application Publication
(10) Pub. No.: US 2026/0045869 A1
(43) Pub. Date: Feb. 12, 2026

(54) CONTROLLER APPLIED TO A POWER CONVERTER

(71) Applicant: Leadtrend Technology Corp., Hsinchu County (TW)

(72) Inventors: Hsiao-Yuan Fan, Hsinchu County (TW); Chung-Wei Lin, Hsinchu County (TW); Han-Wei Chen, Hsinchu City (TW)

(73) Assignee: Leadtrend Technology Corp., Hsinchu County (TW)

(21) Appl. No.: 18/926,343

(22) Filed: Oct. 25, 2024

(30) Foreign Application Priority Data
Aug. 8, 2024 (TW) 113129667

(51) Int. Cl. H02M 1/36; H01L 23/528; H01L 23/532; H01L 27/06; H02M 1/00; H02M 1/34

(52) U.S. Cl. CPC H02M 1/36; H01L 23/53209; H02M 1/0009; H02M 1/344; H10D 84/811; H01L 23/5283; H01L 23/53271; H01L 2223/64

(57) ABSTRACT

A controller applied to a power converter includes a startup and pulse control circuit, a power switch, a startup circuit, and a clamping circuit. The power switch is coupled to a primary side of the power converter and the startup and pulse control circuit, and turned on according to a gate control signal generated by the startup and pulse control circuit. The startup circuit is coupled to the primary side of the power converter, the startup and pulse control circuit and the power switch, and turned on according to a startup signal generated by the startup and pulse control circuit. The clamping circuit is coupled to the startup and pulse control circuit and the power switch, and clamps a current flowing through the startup circuit when the startup circuit is turned on.

### BACKGROUND OF THE INVENTION

### 1. Field of the Invention

The present invention relates to a controller applied to a power converter, and particularly to a controller that can utilize a clamping circuit to clamp a current flowing through a startup circuit when the startup circuit is turned on to reduce switching loss of the startup circuit, thereby increasing efficiency of the controller.

### 2. Description of the Prior Art

One of the prior art integrates individually made chips of a pulse width modulation circuit, a high voltage power switch, a current sensing resistor and a high voltage startup circuit into a package. However, the technology not only consumes area but also has cumbersome packaging process, thereby having high cost.

In addition, another prior art integrates the high voltage startup circuit, the high voltage power switch and the current sensing resistor into a chip, and connects a resistor in series with a drain and a gate of the high voltage startup circuit. Afterward, the another prior art integrates the chip and the pulse width modulation circuit into a package. Although the another prior art can reduce manufacturing cost and packaging process, the another prior art has higher leakage current to make the high voltage startup circuit have higher switching loss.

### SUMMARY OF THE INVENTION

An embodiment of the present invention provides a controller applied to a power converter. The controller includes a startup and pulse control circuit, a power switch, a startup circuit, and a clamping circuit. The power switch is coupled to a primary side of the power converter and the startup and pulse control circuit, and turned on according to a gate control signal generated by the startup and pulse control circuit. The startup circuit is coupled to the primary side of the power converter, the startup and pulse control circuit and the power switch, and turned on according to a startup signal generated by the startup and pulse control circuit. The clamping circuit is coupled to the startup and pulse control circuit and the power switch and clamping a current flowing through the startup circuit when the startup circuit is turned on.

According to one aspect of the present invention, the controller further includes a current detection circuit, wherein the current detection circuit is coupled to the startup and pulse control circuit and the power switch and detects a current flowing through the power switch through the startup and pulse control circuit when the power switch is turned on.

According to one aspect of the present invention, the current detection circuit includes a first metal-oxide-semiconductor field effect transistor and a detection resistor, the power switch is a first high voltage metal-oxide-semiconductor field effect transistor, a drain of the first high voltage metal-oxide-semiconductor field effect transistor is coupled to the primary side of the power converter, a gate of the first high voltage metal-oxide-semiconductor field effect transistor is coupled to the startup and pulse control circuit, and a source of the first high voltage metal-oxide-semiconductor field effect transistor is coupled to ground; wherein a drain and a gate of the first metal-oxide-semiconductor field effect transistor are shared with the first high voltage metal-oxide-semiconductor field effect transistor, and a source of the first metal-oxide-semiconductor field effect transistor is coupled to the startup and pulse control circuit; wherein a first terminal of the detection resistor is coupled to the source of the first metal-oxide-semiconductor field effect transistor, and a second terminal of the detection resistor is coupled to the ground.

According to one aspect of the present invention, an aspect ratio of the gate of the first metal-oxide-semiconductor field effect transistor is in proportion to an aspect ratio of the gate of the first high voltage metal-oxide-semiconductor field effect transistor, and when the first high voltage metal-oxide-semiconductor field effect transistor is turned on according to the gate control signal, the startup and pulse control circuit utilizes a voltage across the detection resistor, the aspect ratio of the gate of the first metal-oxide-semiconductor field effect transistor and the aspect ratio of the gate of the first high voltage metal-oxide-semiconductor field effect transistor to detect a current flowing through the first high voltage metal-oxide-semiconductor field effect transistor.

According to one aspect of the present invention, the power switch, the startup circuit, the clamping circuit and the first metal-oxide-semiconductor field effect transistor are integrated circuits formed on a first chip, the startup and pulse control circuit is an integrated circuit formed on a second chip, and the first chip, the second chip and the detection resistor are integrated into a package.

According to one aspect of the present invention, the clamping circuit includes a second metal-oxide-semiconductor field effect transistor and a high impedance resistor, the startup circuit is a second high voltage metal-oxide-semiconductor field effect transistor, a drain of the second high voltage metal-oxide-semiconductor field effect transistor is coupled to the primary side of the power converter, and a gate and a source of the second high voltage metal-oxide-semiconductor field effect transistor are coupled to the startup and pulse control circuit; wherein a gate and a drain of the second metal-oxide-semiconductor field effect transistor are shared with the second high voltage metal-oxide-semiconductor field effect transistor, a first terminal of the high impedance resistor is coupled to the gate of the second metal-oxide-semiconductor field effect transistor, and a second terminal of the high impedance resistor is coupled to a source of the second metal-oxide-semiconductor field effect transistor.

According to one aspect of the present invention, when the second high voltage metal-oxide-semiconductor field effect transistor and the second metal-oxide-semiconductor field effect transistor are turned on according to the startup signal, the clamping circuit utilizes a current flowing through the second metal-oxide-semiconductor field effect transistor and the high impedance resistor to clamp the current flowing through the startup circuit.

According to one aspect of the present invention, the second high voltage metal-oxide-semiconductor field effect transistor is a junction gate field-effect transistor (JFET), or an enhancement mode metal-oxide-semiconductor field effect transistor, or a depletion mode metal-oxide-semiconductor field effect transistor; wherein the second metal-oxide-semiconductor field effect transistor is a junction gate field-effect transistor, or an enhancement mode metal-oxide-semiconductor field effect transistor, or a depletion mode metal-oxide-semiconductor field effect transistor.

According to one aspect of the present invention, the gate control signal is a pulse width modulation signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a controller applied to a power converter according to an embodiment of the present invention.

FIG. 2 is a diagram illustrating a layout of the controller.

FIG. 3 is a cross-section view along a cutline A-A shown in FIG. 2.

### DETAILED DESCRIPTION

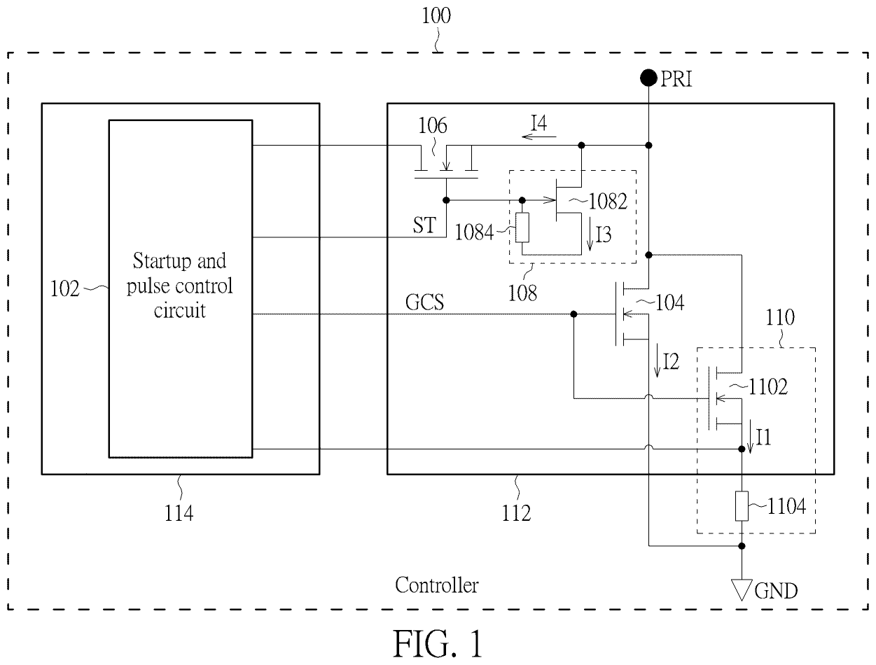

Please refer to FIG. 1. FIG. 1 is a diagram illustrating a controller 100 applied to a power converter according to an embodiment of the present invention. As shown in FIG. 1, the controller 100 includes a startup and pulse control circuit 102, a power switch 104, a startup circuit 106, a clamping circuit 108, and a current detection circuit 110. As shown in FIG. 1, the power switch 104 is a first high voltage metal-oxide-semiconductor field effect transistor, a drain of the power switch 104 (the first high voltage metal-oxide-semiconductor field effect transistor) is coupled to a primary side PRI of the power converter (not shown in FIG. 1), a gate of power switch 104 (the first high voltage metal-oxide-semiconductor field effect transistor) is coupled to the startup and pulse control circuit 102, and a source of the power switch 104 (the first high voltage metal-oxide-semiconductor field effect transistor) is coupled to ground GND. In addition, as shown in FIG. 1, the startup circuit 106 is a second high voltage metal-oxide-semiconductor field effect transistor, a drain of the startup circuit 106 (the second high voltage metal-oxide-semiconductor field effect transistor) is coupled to the primary side PRI of the power converter, and a gate and a source of the startup circuit 106 (the second high voltage metal-oxide-semiconductor field effect transistor) are coupled to the startup and pulse control circuit 102. In addition, in one embodiment of the present invention, the startup circuit 106 (the second high voltage metal-oxide-semiconductor field effect transistor) is a junction gate field-effect transistor (JFET), or an enhancement mode metal-oxide-semiconductor field effect transistor, or a depletion mode metal-oxide-semiconductor field effect transistor. In addition, as shown in FIG. 1, the clamping circuit 108 includes a second metal-oxide-semiconductor field effect transistor 1082 and a high impedance resistor 1084, wherein a gate and a drain of the second metal-oxide-semiconductor field effect transistor 1082 are shared with the startup circuit 106 (the second high voltage metal-oxide-semiconductor field effect transistor), a first terminal of the high impedance resistor 1084 is coupled to the gate of the second metal-oxide-semiconductor field effect transistor 1082, and a second terminal of the high impedance resistor 1084 is coupled to a source of the second metal-oxide-semiconductor field effect transistor 1082. In addition, in one embodiment of the present invention, the second metal-oxide-semiconductor field effect transistor 1082 is a junction gate field-effect transistor, or an enhancement mode metal-oxide-semiconductor field effect transistor, or a depletion mode metal-oxide-semiconductor field effect transistor. In addition, as shown in FIG. 1, the current detection circuit 110 includes a first metal-oxide-semiconductor field effect transistor 1102 and a detection resistor 1104, a drain and a gate of the first metal-oxide-semiconductor field effect transistor 1102 are shared with the power switch 104 (the first high voltage metal-oxide-semiconductor field effect transistor), and a source of the first metal-oxide-semiconductor field effect transistor 1102 is coupled to the startup and pulse control circuit 102; wherein a first terminal of the detection resistor 1104 is coupled to the source of the first metal-oxide-semiconductor field effect transistor 1102, and a second terminal of the detection resistor 1104 is coupled to the ground GND.

As shown in FIG. 1, when the startup circuit 106 (the second high voltage metal-oxide-semiconductor field effect transistor) and the second metal-oxide-semiconductor field effect transistor 1082 are turned on according to a startup signal ST generated by the startup and pulse control circuit 102, the clamping circuit 108 utilizes a current I3 flowing through the second metal-oxide-semiconductor field effect transistor 1082 and the high impedance resistor 1084 to clamp a current I4 flowing through startup circuit 106 (the second high voltage metal-oxide-semiconductor field effect transistor). Therefore, because the current I4 flowing through startup circuit 106 (the second high voltage metal-oxide-semiconductor field effect transistor) is clamped, the present invention can reduce power loss of the startup circuit 106.

In addition, in one embodiment of the present invention, an aspect ratio of the gate of the first metal-oxide-semiconductor field effect transistor 1102 is in proportion to an aspect ratio of the gate of the power switch 104 (the first high voltage metal-oxide-semiconductor field effect transistor). Therefore, when the power switch 104 (the first high voltage metal-oxide-semiconductor field effect transistor) is turned on according to a gate control signal GCS generated by the startup and pulse control circuit 102, the startup and pulse control circuit 102 can first utilize a voltage across the detection resistor 1104 to detect a current I1 flowing through first metal-oxide-semiconductor field effect transistor 1102, wherein the gate control signal GCS is a pulse width modulation signal. Because the aspect ratio of the gate of the first metal-oxide-semiconductor field effect transistor 1102 is in proportion to the aspect ratio of the gate of the power switch 104 (the first high voltage metal-oxide-semiconductor field effect transistor), the current I1 flowing through first metal-oxide-semiconductor field effect transistor 1102 is also in proportion to a current I2 flowing through power switch 104 (the first high voltage metal-oxide-semiconductor field effect transistor). Thus, the current I2 can be obtained according to the current I1, so that the startup and pulse control circuit 102 can control a frequency of the gate control signal GCS according to the current I2.

In addition, in one embodiment of the present invention, the power switch 104, the startup circuit 106, the clamping circuit 108 and the first metal-oxide-semiconductor field effect transistor 1102 are integrated circuits formed on a first chip 112, the startup and pulse control circuit 102 is an integrated circuit formed on a second chip 114, and the first chip 112, the second chip 114 and the detection resistor 1104 are integrated into a package.

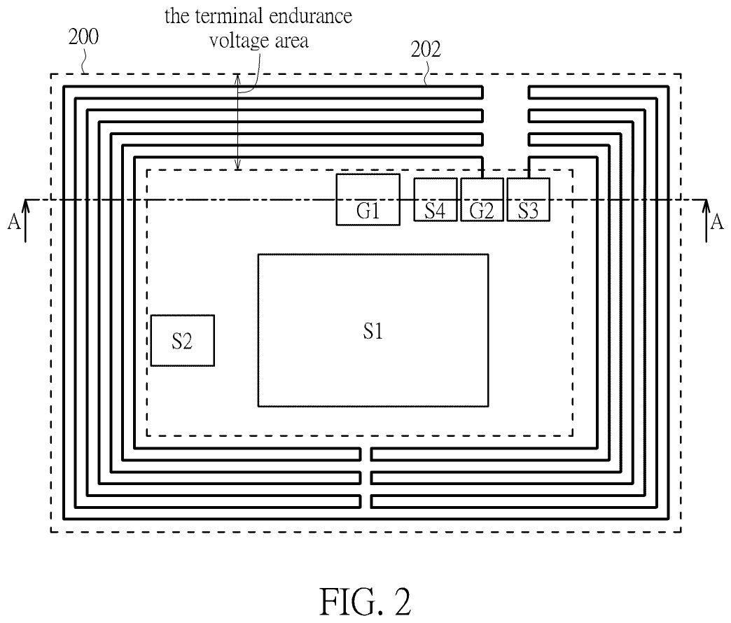

Please refer to FIG. 2. FIG. 2 is a diagram illustrating a layout of the controller 100. As shown in FIG. 2, G1 is the gate of the power switch 104 and the first metal-oxide-semiconductor field effect transistor 1102; S1 is the source of the power switch 104; S2 is the source of the first metal-oxide-semiconductor field effect transistor 1102, wherein the current I1 flowing through the source S2 is in proportion to the current I2 flowing through the source S1; G2 is the gate of the second metal-oxide-semiconductor field effect transistor 1082 and the startup circuit 106; S3 is the source of the second metal-oxide-semiconductor field effect transistor 1082; S4 is the source of the startup circuit 106; a terminal endurance voltage area is located within a dotted frame 200, wherein solid lines 202 (e.g. a polysilicon resistor) within the terminal endurance voltage area are the high impedance resistor 1084, and the high impedance resistor 1084 is between the source of the second metal-oxide-semiconductor field effect transistor 1082 and the gate of second metal-oxide-semiconductor field effect transistor 1082. In addition, the power switch 104, the first metal-oxide-semiconductor field effect transistor 1102, the second metal-oxide-semiconductor field effect transistor 1082 and the startup circuit 106 share a drain, wherein the drain (not shown in FIG. 2) is located at a bottom of the first chip 112.

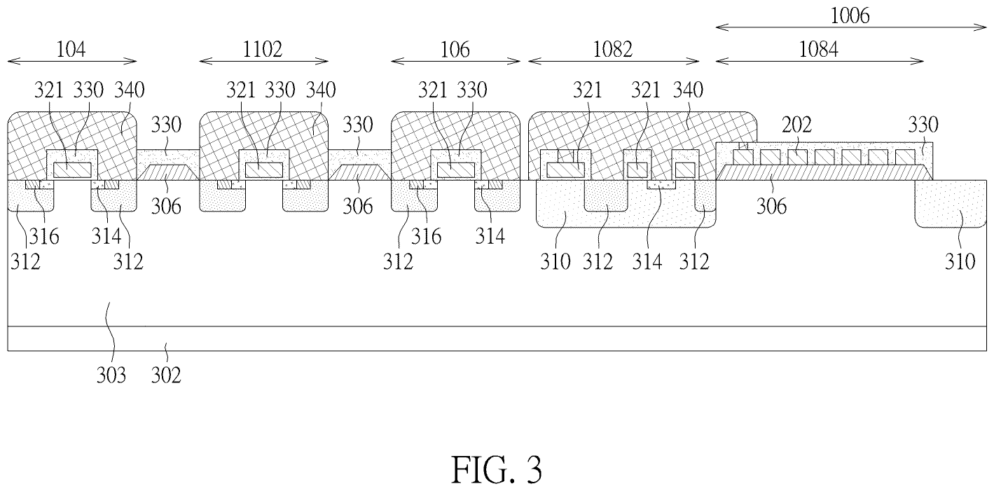

Next, please refer to FIG. 3. FIG. 3 is a cross-section view along a cutline A-A shown in FIG. 2, wherein although the first metal-oxide-semiconductor field effect transistor 1102 is not located at the cutline A-A, the first metal-oxide-semiconductor field effect transistor 1102 is still shown in the cross-section view for describing the present invention. As shown in FIGS. 3, 1006 is the terminal endurance voltage area shown in FIG. 2, the high impedance resistor 1084 is formed by winding the solid lines 202 (e.g. a polysilicon resistor) within the terminal endurance voltage area 1006, and the power switch 104, the first metal-oxide-semiconductor field effect transistor 1102, the startup circuit 106 and the second metal-oxide-semiconductor field effect transistor 1082 share the terminal endurance voltage area 1006. In addition, as shown in FIGS. 3, 302 is a substrate of the first chip 112, 303 is an N type epitaxial layer, 310 is a first doping well, 312 is a second doping well, 314 is a third doping well, 316 is a fourth doping well, 306 and 330 are insulation materials, 321 is polysilicon, and 340 is a metal material.

To sum up, the present invention can utilize the clamping circuit to clamp the current flowing through the startup circuit to reduce switching loss of the startup circuit when the startup circuit is turned on, thereby improving efficiency of the controller.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A controller applied to a power converter, comprising:
a startup and pulse control circuit;
a power switch coupled to a primary side of the power converter and the startup and pulse control circuit, and turned on according to a gate control signal generated by the startup and pulse control circuit;
a startup circuit coupled to the primary side of the power converter, the startup and pulse control circuit and the power switch, and turned on according to a startup signal generated by the startup and pulse control circuit; and
a clamping circuit coupled to the startup and pulse control circuit and the power switch and clamping a current flowing through the startup circuit when the startup circuit is turned on.

2. The controller of claim 1, further comprising:
a current detection circuit coupled to the startup and pulse control circuit and the power switch and detecting a current flowing through the power switch through the startup and pulse control circuit when the power switch is turned on.

3. The controller of claim 2, wherein the current detection circuit comprises a first metal-oxide-semiconductor field effect transistor and a detection resistor, the power switch is a first high voltage metal-oxide-semiconductor field effect transistor, a drain of the first high voltage metal-oxide-semiconductor field effect transistor is coupled to the primary side of the power converter, a gate of the first high voltage metal-oxide-semiconductor field effect transistor is coupled to the startup and pulse control circuit, and a source of the first high voltage metal-oxide-semiconductor field effect transistor is coupled to ground; wherein a drain and a gate of the first metal-oxide-semiconductor field effect transistor are shared with the first high voltage metal-oxide-semiconductor field effect transistor, and a source of the first metal-oxide-semiconductor field effect transistor is coupled to the startup and pulse control circuit; wherein a first terminal of the detection resistor is coupled to the source of the first metal-oxide-semiconductor field effect transistor, and a second terminal of the detection resistor is coupled to the ground.

4. The controller of claim 3, wherein an aspect ratio of the gate of the first metal-oxide-semiconductor field effect transistor is in proportion to an aspect ratio of the gate of the first high voltage metal-oxide-semiconductor field effect transistor, and when the first high voltage metal-oxide-semiconductor field effect transistor is turned on according to the gate control signal, the startup and pulse control circuit utilizes a voltage across the detection resistor, the aspect ratio of the gate of the first metal-oxide-semiconductor field effect transistor and the aspect ratio of the gate of the first high voltage metal-oxide-semiconductor field effect transistor to detect a current flowing through the first high voltage metal-oxide-semiconductor field effect transistor.

5. The controller of claim 3, wherein the power switch, the startup circuit, the clamping circuit and the first metal-oxide-semiconductor field effect transistor are integrated circuits formed on a first chip, the startup and pulse control circuit is an integrated circuit formed on a second chip, and the first chip, the second chip and the detection resistor are integrated into a package.

6. The controller of claim 1, wherein the clamping circuit comprises a second metal-oxide-semiconductor field effect transistor and a high impedance resistor, the startup circuit is a second high voltage metal-oxide-semiconductor field effect transistor, a drain of the second high voltage metal-oxide-semiconductor field effect transistor is coupled to the primary side of the power converter, and a gate and a source of the second high voltage metal-oxide-semiconductor field effect transistor are coupled to the startup and pulse control circuit; wherein a gate and a drain of the second metal-oxide-semiconductor field effect transistor are shared with the second high voltage metal-oxide-semiconductor field effect transistor, a first terminal of the high impedance resistor is coupled to the gate of the second metal-oxide-semiconductor field effect transistor, and a second terminal of the high impedance resistor is coupled to a source of the second metal-oxide-semiconductor field effect transistor.

7. The controller of claim 6, wherein when the second high voltage metal-oxide-semiconductor field effect transistor and the second metal-oxide-semiconductor field effect transistor are turned on according to the startup signal, the clamping circuit utilizes a current flowing through the second metal-oxide-semiconductor field effect transistor and the high impedance resistor to clamp the current flowing through the startup circuit.

8. The controller of claim 6, wherein the second high voltage metal-oxide-semiconductor field effect transistor is a junction gate field-effect transistor (JFET), or an enhancement mode metal-oxide-semiconductor field effect transistor, or a depletion mode metal-oxide-semiconductor field effect transistor; wherein the second metal-oxide-semiconductor field effect transistor is a junction gate field-effect transistor, or an enhancement mode metal-oxide-semiconductor field effect transistor, or a depletion mode metal-oxide-semiconductor field effect transistor.

9. The controller of claim 1, wherein the gate control signal is a pulse width modulation signal.
